(19) United States
(12) Patent Application Publication
(10) Pub. No.: US 2025/0306087 A1
(43) Pub. Date: Oct. 2, 2025

(54) MICRO-INTEGRATED CIRCUIT DETECTION SYSTEM AND DETECTION METHOD THEREOF

(71) Applicant: AUO Corporation, Hsinchu City (TW)

(72) Inventors: Ya-Pei KUO, Hsinchu City (TW); Chun-Lin CHEN, Hsinchu City (TW)

(21) Appl. No.: 18/916,753

(22) Filed: Oct. 16, 2024

(30) Foreign Application Priority Data
Mar. 29, 2024 (TW) 113112189

(51) Int. Cl. G01R 31/28

(52) U.S. Cl. CPC G01R 31/2884

(57) ABSTRACT

A micro-integrated circuit (μIC) detection method is applicable for detecting a plurality of μICs on a panel. The μIC detection method includes: turning on the μICs arranged in columns and rows on the panel; scanning the μICs in each of the rows in sequence to obtain a total current of the μICs in each of the rows; and determining at least one of the μICs in one of the rows to be abnormal when the total current of the μICs in the one of the rows does not match a preset total current.

### RELATED APPLICATIONS

This application claims priority to Taiwan Application Serial Number 113112189, filed Mar. 29, 2024, which is herein incorporated by reference.

### BACKGROUND

### Field of Disclosure

The present disclosure relates to a micro-integrated circuit detection system and a detection method thereof.

### Description of Related Art

Micro light-emitting diodes (μLEDs) have the advantages of high brightness, high reliability, and low power consumption, etc. Therefore, they have gradually been widely applied to automotive display systems, wearable devices, and various display screens, etc. With the increase in demand for the miniaturization of electronic devices, μLEDs are usually combined with micro-integrated circuits (μICs) to be applied, and the two are transferred to a target substrate through a mass transfer technology. Finally, the electrical connection between μLEDs and μICs is realized by forming pads and wires, etc. to form a microsystem on the target substrate.

In the mass transfer process, the μLEDs and the μICs that transferred to the target substrate need to be detected before the subsequent processes can be performed continuously. However, such a detection process results in a system or detection personnel being unable to distinguish whether an abnormality is from the μLEDs or the μICs as soon as possible when detecting and finding the abnormality.

For the foregoing reason, there is a need to solve the above-mentioned problem by providing a μIC detection system and a detection method thereof.

### SUMMARY

A detection method of a micro-integrated circuit (μIC) is provided. The detection method of the μIC is applicable for detecting a plurality of μICs on a panel. The detection method includes: turning on the μICs arranged in columns and rows on the panel; scanning the μICs in each of the columns in sequence to obtain a total current of the μICs in each of the columns; and determining whether the total current of the μICs in each of the columns matches a preset total current to determine whether at least one of the μICs in each of the columns is abnormal.

In the foregoing, the at least one of the μICs in one of the columns is abnormal, and the detection method further includes: scanning the one of the columns where the total current of the μICs in the one of the columns does not match the preset total current; turning on each of the μICs in the one of the columns in sequence to obtain a driving current of each of the μICs in the one of the columns; and determining which one of the μICs in the one of the columns is abnormal by determining whether the driving current of each of the μICs in the one of the columns matches a preset driving current.

In the foregoing, the panel includes at least two areas, and the at least one of the μICs in the one of the columns is abnormal, and the detection method further includes: scanning the one of the columns where the total current of the μICs in the one of the columns does not match the preset total current; turning on the μICs respectively located in the at least two areas in the one of the columns in sequence to obtain at least two area total currents; determining which one of the at least two areas an abnormality occurred in by determining whether the at least two area total currents of the at least two areas matches a preset area total current; and wherein one of the at least two areas is determined to be abnormal, and the detection method further comprises: turning on the μICs respectively located in at least two sub-areas of the one of the at least two areas to obtain at least two sub-area total currents; and determining which one of the at least two sub-areas the abnormality occurred in by determining whether the at least two sub-area total currents of the at least two sub-areas matches a preset sub-area total current.

In the foregoing, each of the μICs includes a plurality of sub-pixel pins. Each of the sub-pixel pins includes a positive terminal and a negative terminal, and the positive terminal and the negative terminal are configured to be connected to a sub-pixel. The detection method further includes: turning on the sub-pixel connected to each of the sub-pixel pins and each of the μICs to determine whether the sub-pixel connected to each of the sub-pixel pins is lit or not; providing a ground potential to a negative terminal of the unlit sub-pixel, and providing an on potential to a positive terminal of the unlit sub-pixel; turning on a corresponding one of the μICs for driving the unlit sub-pixel, wherein when the unlit sub-pixel is still not lit, determining that the unlit sub-pixel is abnormal; and turning off the corresponding one of the μICs for driving the unlit sub-pixel, wherein when the unlit sub-pixel is lit, determining that the corresponding one of the μICs is abnormal.

The present disclosure provides a detection system of a micro-integrated circuit (μIC) applicable for detecting a plurality of μICs arranged in columns and rows on a panel. The detection system includes a controller, a power circuit, and a current detection circuit. The controller is electrically connected to the μICs and configured to provide a scanning signal so as to scan the μICs in each of the columns in sequence. The power circuit is configured to provide a power voltage to turn on the μICs. The current detection circuit is electrically connected between the power circuit and the μICs and configured to detect a total current of the μICs in each of the columns after being scanned by the scan signal. The total current of the μICs in each of the columns is determined to be abnormal based on determining whether the total current of the μICs in each of the columns matches a preset total current.

In the foregoing, each of the μICs further includes a first sub-pixel pin, a second sub-pixel pin, and a third sub-pixel pin, and the current detection circuit further includes a plurality of current detection modules. The current detection modules are respectively corresponding to the μICs, and configured to detect a first sub-pixel current, a second sub-pixel current, and a third sub-pixel current respectively flowing through the first sub-pixel pin, the second sub-pixel pin, and the third sub-pixel pin of each of the μICs.

In the foregoing, each of the current detection modules further includes a first testing pad, a second testing pad, and a third testing pad. The first testing pad is corresponding to the first sub-pixel pin. The second testing pad is corresponding to the second sub-pixel pin. The third testing pad is corresponding to the third sub-pixel pin.

In the foregoing, each of the current detection modules further includes a first sampling resistor, a second sampling resistor, and a third sampling resistor. The first sampling resistor is electrically connected between the first sub-pixel pin and the power circuit. The second sampling resistor is electrically connected between the second sub-pixel pin and the power circuit. The third sampling resistor is electrically connected between the third sub-pixel pin and the power circuit.

In the foregoing, each of the current detection modules further includes an analog-to-digital converter (ADC). The ADC is configured to receive voltages across the first sampling resistor, the second sampling resistor, and the third sampling resistor to obtain the first sub-pixel current, the second sub-pixel current, and the third sub-pixel current.

In the foregoing, the total current includes a first sub-pixel total current, a second sub-pixel total current, and a third sub-pixel total current, and each of the μICs further includes a first sub-pixel pin, a second sub-pixel pin, and a third sub-pixel pin. The first sub-pixel pin is configured to allow a first sub-pixel current to flow through during a detection period. The second sub-pixel pin is configured to allow a second sub-pixel current to flow through during the detection period. The third sub-pixel pin is configured to allow a third sub-pixel current to flow through during the detection period. The first sub-pixel total current is a sum of the first sub-pixel current of each of the μICs in a same one of the columns. The second sub-pixel total current is a sum of the second sub-pixel current of each of the μICs in the same one of the columns. The third sub-pixel total current is a sum of the third sub-pixel current of each of the μICs in the same one of the columns.

In the foregoing, the current detection circuit further includes a plurality of current detection modules respectively corresponding to the columns and configured to detect the total current of each of the columns, and the detection system further includes a plurality of switch circuits. The switch circuits are respectively corresponding to the current detection modules, and each of the switch circuits is electrically connected between a corresponding one of the current detection modules and each of the μICs in the same one of the columns.

In the foregoing, each of the switch circuits further includes a plurality of first switch elements. The first switch elements are respectively electrically connected between the corresponding one of the current detection modules and the first sub-pixel pin of each of the μICs in a same one of the columns.

In the foregoing, each of the switch circuits further includes a plurality of second switch elements. The second switch elements are respectively electrically connected between the corresponding one of the current detection modules the second sub-pixel pin of each of the μICs in the same one of the columns.

In the foregoing, each of the switch circuits further includes a plurality of third switch elements. The third switch elements are respectively electrically connected between the corresponding one of the current detection modules the third sub-pixel pin of each of the μICs in the same one of the columns.

In the foregoing, each of the plurality of current detection modules further includes a sampling resistor and an ADC. The sampling resistor is electrically connected between the power circuit and the corresponding one of the plurality of switch circuits. The ADC is configured to receive cross-voltage across the sampling resistor to selectively obtain the first sub-pixel current, the second sub-pixel current, the third sub-pixel current, the first sub-pixel total current, the second sub-pixel total current, the third sub-pixel total current or the total current depending on whether the plurality of switch circuits are turned on or turned off.

In the foregoing, each of the plurality of current detection modules further includes a testing pad. The testing pad is electrically connected between the sampling resistor and the corresponding one of the plurality of switch circuits.

It is to be understood that both the foregoing general description and the following detailed description are by examples, and are intended to provide further explanation of the disclosure as claimed.

### BRIEF DESCRIPTION OF THE DRAWINGS

The accompanying drawings are included to provide a further understanding of the present disclosure, and are incorporated in and constitute a part of this specification. The drawings illustrate embodiments of the present disclosure and, together with the description, serve to explain the principles of the present disclosure.

FIG. 1 depicts a schematic diagram of a micro-integrated circuit (μIC) detection system according to one embodiment of the present disclosure.

FIG. 2 depicts a schematic diagram of a flow of a transfer process of μICs and micro light-emitting diodes (μLEDs) according to one embodiment of the present disclosure.

FIG. 3 depicts a detailed structural schematic diagram of a μIC detection system according to one embodiment of the present disclosure.

FIG. 4 depicts a detailed structural schematic diagram of a μIC detection system according to another embodiment of the present disclosure.

FIG. 5 depicts a flowchart of a μIC detection method according to one embodiment of the present disclosure.

FIG. 6 depicts a flowchart of a μIC detection method according to another embodiment of the present disclosure.

FIG. 7 depicts a flowchart of a μIC detection method according to still another embodiment of the present disclosure.

FIGS. 8A to 8D depict schematic diagrams of the μIC detection method in FIG. 7.

FIG. 9 depicts a flowchart of a μIC detection method according yet another embodiment of the present disclosure.

### DESCRIPTION OF THE EMBODIMENTS

The following disclosure provides many different embodiments, or examples, for implementing different features of the present disclosure. Embodiments of components and configurations are described below. These are, of course, merely examples and are not intended to be limiting. In addition, the present disclosure may repeat reference characters and/or numerals in the various examples. This repetition is for the purpose of simplicity and clarity and does not in itself limit a relationship between the various embodiments and/or components discussed.

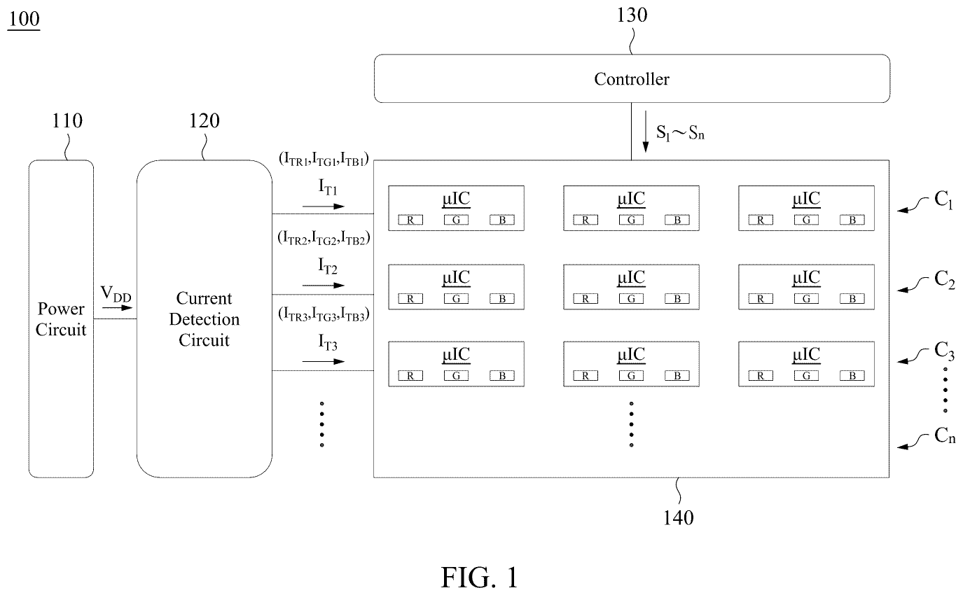

A description is provided with reference to FIG. 1. FIG. 1 depicts a schematic diagram of a micro-integrated circuit (μIC) detection system 100 according to one embodiment of the present disclosure. The μIC detection system 100 includes a power circuit 110, a current detection circuit 120, and a controller 130, and is applicable for detecting a plurality of μICs arranged in columns and rows on a panel 140.

The μICs are configured to drive pixel units (not shown), and each of them includes a first sub-pixel pin R, a second sub-pixel pin G, and a third sub-pixel pin B to be respectively configured to drive a red sub-pixel, a green sub-pixel, and a blue sub-pixel in each of the pixel units. In some embodiments of the present disclosure, these sub-pixels are micro light-emitting diodes (μLEDs). In addition, both the μICs and the μLEDs may be transferred to the target panel 140 through the mass transfer technology so as to form a microsystem on the panel 140.

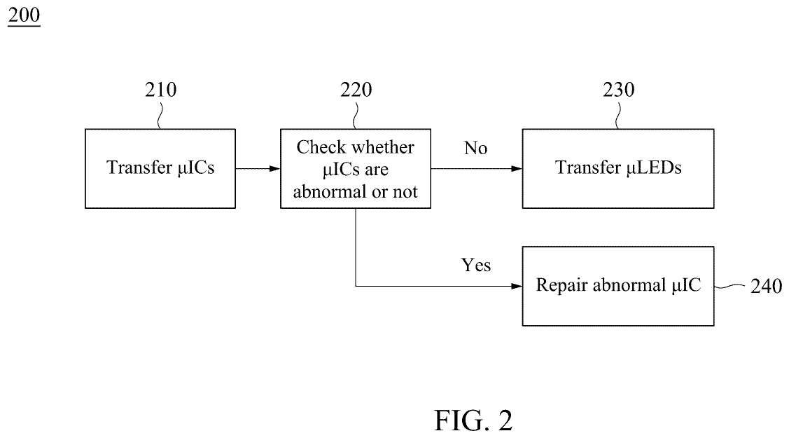

A description is provided with reference to FIG. 2. FIG. 2 further depicts a schematic diagram of a flow 200 of transfer processes of the μICs and the μLEDs according to one embodiment of the present disclosure. As can be found from FIG. 2, a transfer process of the μICs (Step 210) goes earlier than a transfer process of the μLEDs (Step 230), and abnormal detection of the μICs (Step 220) has been completed before the μLEDs are transferred. As a result, abnormal μIC(s) can be repaired or replaced first in Step 240.

Compared to transferring both μICs and μLEDs to panel 140 and then performing abnormal detection, the method of transferring μICs first and performing abnormal detection has a higher detection efficiency. In other words, after the μICs and μLEDs are transferred to the panel 140, if an abnormality is detected (e.g., the μLED(s) is/are not lit or not turned on), the abnormal problem of the μIC(s) can first be excluded to further quickly distinguish whether the problem is from the μLED(s) or from some other possible abnormal problems.

With additional reference to FIG. 1. The controller 130 is electrically connected to the μICs on the panel 140, and is configured to provide scanning signals S₁-Sₙ so as to scan the μICs in each of the columns C₁-Cₙ in sequence. The power circuit 110 is configured to provide a power voltage V_{DD} for detection so as to selectively turn on each of the μICs on the panel 140. In some embodiments, the power voltage V_{DD} may be supplied to the panel 140 directly from the controller 130 so as to selectively turn on each of the μICs on the panel 140. In some other embodiments, the μIC detection system 100 may have both the power voltage V_{DD} of the power circuit 110 and the power voltage V_{DD} (not shown) of the controller 130, and it is also within the implementation scope of the present disclosure.

The current detection circuit 120 is electrically connected between the power circuit 110 and the μICs on the panel 140, and is further configured to detect a total current I_{T1}-I_{T3} of the μICs in each of the columns C₁-Cₙ after each of the columns C₁-Cₙ is scanned by the scanning signals S₁-Sₙ. When the total current of the μICs in one of the columns does not match a preset total current, it is determined that at least one of the μICs in this one of the columns to be abnormal.

For example, a first column C₁ on the panel 140 includes three μICs, and a minimum driving current of the first sub-pixel pin R of each μIC is 10 μA, a minimum driving current of the second sub-pixel pin G of each μIC is 10 μA, and a minimum driving current of the third sub-pixel pin B of each μIC is 10 μA. Therefore, a sum of the minimum driving currents of each of the μICs should be 30 μA, which means the preset total current of the first column C₁ should be 90 μA (30 μA×3 μICs). If the total current I_{T1} measured by the current detection circuit 120 does not match 90 μA, for example, a difference value between the total current I_{T1} detected by the current detection circuit 120 and 90 μA exceeds a preset difference value (for example, the total current I_{T1} is 95 μA, and the difference value from 90 μA is 5 μA, which exceeds the preset difference value by 1 μA), it is determined that there is an abnormal one (or more) μIC(s) in the first column C₁.

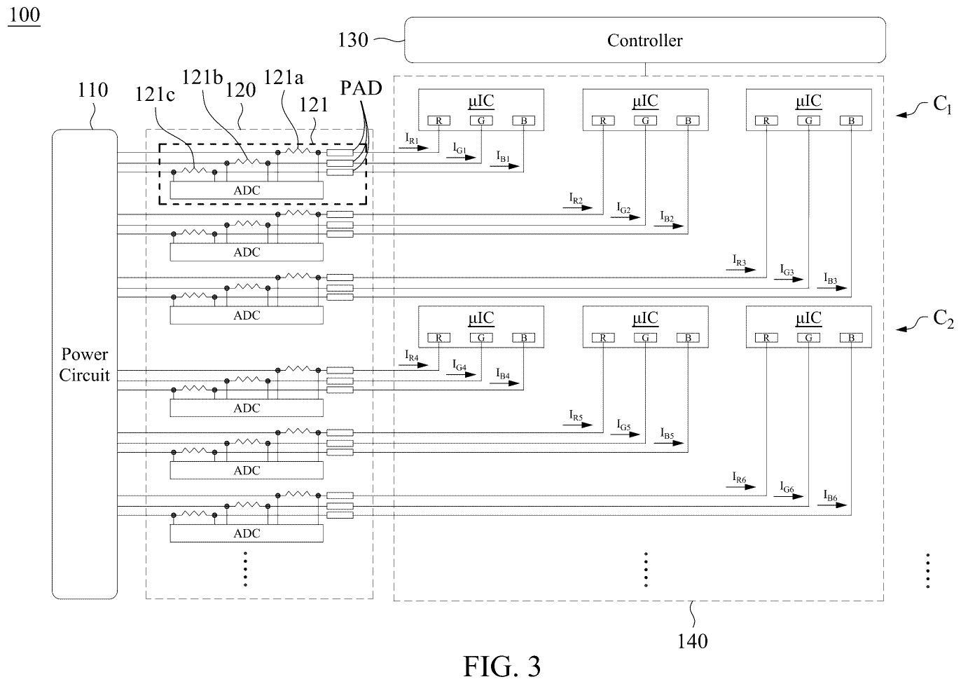

A description is provided with reference to FIG. 3. FIG. 3 depicts a detailed structural schematic diagram of the μIC detection system 100 according to one embodiment of the present disclosure. The current detection circuit 120 further includes a plurality of current detection modules 121 corresponding to the μICs one on one. Each of the current detection modules 121 is configured to detect the first sub-pixel pin R, the second sub-pixel pin G, and the third sub-pixel pin B of the corresponding μIC, so as to obtain a first sub-pixel current I_{Rx}, a second sub-pixel current I_{Gx}, and a third sub-pixel current I_{Bx} respectively flowing through these pins. In the embodiment depicted in FIG. 3, the current detection circuit 120 includes six current detection modules 121 to respectively detect six μICs. The first sub-pixel current I_{Rx} includes I_{R1}-I_{R6}. The second sub-pixel current I_{Gx} includes I_{G1}-I_{G6}. The third sub-pixel current I_{Bx} includes I_{B1}-I_{B6}. It should be understood that FIG. 3 is only taken for example. In fact, numbers of the μICs and the current detection modules 121 may be increased or decreased depending on practical needs.

Each of the current detection modules 121 includes a first sampling resistor 121a, a second sampling resistor 121b, a third sampling resistor 121c, and an analog-to-digital converter (ADC). The first sampling resistor 121a is electrically connected between the first sub-pixel pin R and the power circuit 110, the second sampling resistor 121b is electrically connected between the second sub-pixel pin G and the power circuit 110, and the third sampling resistor 121c is electrically connected between the third sub-pixel pin B and the power circuit 110.

The ADC is configured to receive cross-voltages (analog signals) across the first sampling resistor 121a, the second sampling resistor 121b, and the third sampling resistor 121c to convert the analog signals into digital signals, and to calculate the first sub-pixel current I_{Rx}, the second sub-pixel current I_{Gx}, and the third sub-pixel current I_{Bx} of each of the μICs based on the sampling resistors and the cross-voltages.

Additionally, for the sake of simplicity, FIG. 3 only frames and marks one of the current detection modules 121 and its components as an example. It should be understood that the current detection circuit 120 depicted in FIG. 3 includes multiple current detection modules 121. In some embodiments of the present disclosure, each of the current detection modules 121 further includes testing pads PAD corresponding to the first sub-pixel pin R, the second sub-pixel pin G, and the third sub-pixel pin B, respectively, which may pull the first sub-pixel pin R, the second sub-pixel pin G, and the third sub-pixel pin B out of the panel 140, respectively, so that the current detection module 121 may obtain detection data more conveniently.

A description is provided with reference to FIG. 1 and FIG. 3. In greater detail, take the first column C₁ for example. The total current I_{T1} shown in FIG. 1 includes a first sub-pixel total current I_{TR1}, a second sub-pixel total current I_{TG1}, and a third sub-pixel total current I_{TB1}. The first sub-pixel total current I_{TR1} is a sum of the first sub-pixel current I_{Rx} of each of the μICs in the first column C₁ (that is, I_{TR1}=I_{R1}+I_{R2}+I_{R3}). The second sub-pixel total current I_{TG1} is a sum of the second sub-pixel current I_{Gx} of each of the μICs in the first column C₁ (that is, I_{TG1}=I_{G1}+I_{G2}+I_{G3}). The third sub-pixel total current I_{TB1} is a sum of the third sub-pixel current I_{Bx} of each of the μICs in the first column C₁ (that is, I_{TB1}=I_{B1}+I_{B2}+I_{B3}). As a result, the total current I_{T1} of the first column C₁ is a sum of the first sub-pixel total current I_{TR1}, the second sub-pixel total current I_{TG1}, and the third sub-pixel total current I_{TB1} (that is, I_{T1}=I_{TR1}+I_{TG1}+I_{TB1}).

For example, under normal circumstances, the first sub-pixel currents I_{R1}, I_{R2} and I_{R3} measured by the three current detection modules 121 for detecting the first column C₁ in FIG. 3 should all be 10 μA (that is, the minimum driving current of the first sub-pixel pin R), the second sub-pixel currents I_{G1}, I_{G2} and I_{G3} measured by the three current detection modules 121 for detecting the first column C₁ in FIG. 3 should all be 10 μA (that is, the minimum driving current of the second sub-pixel pin G), and the third sub-pixel currents I_{B1}, I_{B2} and I_{B3} measured by the three current detection modules 121 for detecting the first column C₁ in FIG. 3 should all be 10 μA (that is, the minimum driving current of the third sub-pixel pin B). Therefore, the first sub-pixel total current I_{TR1} of the first column C₁ finally obtained by the current detection circuit 120 should be 30 μA (I_{R1}+I_{R2}+I_{R3}), the second sub-pixel total current I_{TG1} of the first column C₁ finally obtained by the current detection circuit 120 should be 30 μA (that is, I_{G1}+I_{G2}+I_{G3}), and the third sub-pixel total current I_{TB1} of the first column C₁ finally obtained by the current detection circuit 120 should be 30 μA (I_{B1}+I_{B2}+I_{B3}) to further calculate the total current I_{T1} to be 90 μA (I_{TR1}+I_{TG1}+I_{TB1}).

On the contrary, when the total current I_{T1} of the μICs in the first column C₁ does not match the preset total current (90 μA, for example, the difference value between the two exceeds the preset difference value), it is determined that at least one of the μICs in the first column C₁ is abnormal. By using the above example of detecting the first column C₁, the detection method of the other columns C₂-Cₙ should be readily understood, so a description in this regard is not provided. In addition to that, the numerical values mentioned above are only taken for example. In fact, other numerical values may be possible depending on needs or actual applications, and the present disclosure is not limited in this regard.

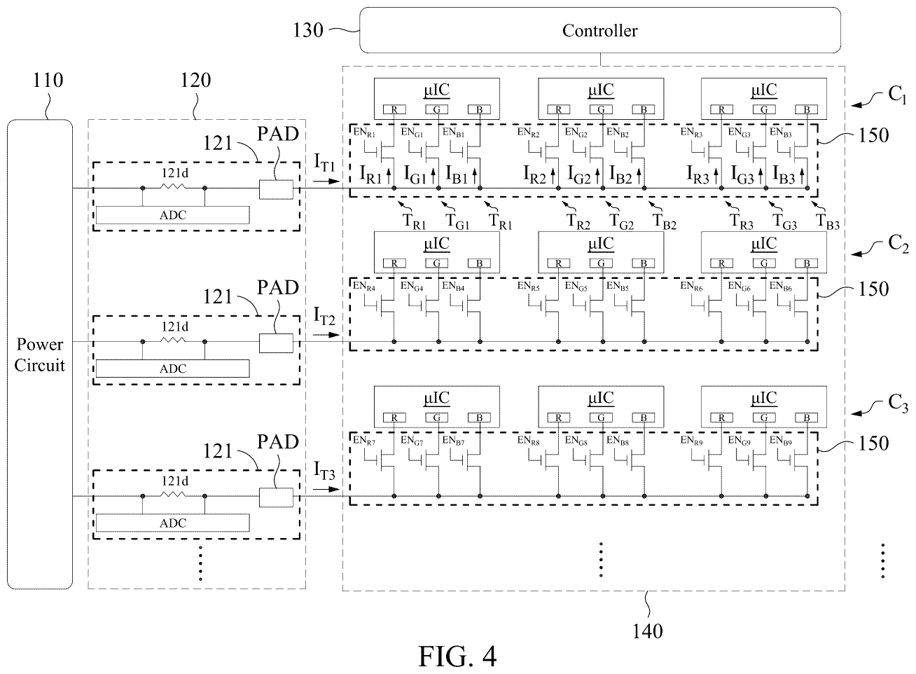

A description is provided with reference to FIG. 4. FIG. 4 depicts a detailed structural schematic diagram of the μIC detection system 100 according to another embodiment of the present disclosure. The current detection circuit 120 includes the plurality of current detection modules 121 correspondingly detecting the columns C₁-Cₙ, and is configured to selectively detect the total currents I_{T1}-I_{T3}, the first sub-pixel total current I_{TR1}, the second sub-pixel total current I_{TG1}, and the third sub-pixel total current I_{TB1} of each of the columns C₁-Cₙ, or the first sub-pixel current I_{Rx}, the second sub-pixel current I_{Gx}, and the third sub-pixel current I_{Bx} of each of the μICs. In such an embodiment, the μIC detection system 100 further includes a plurality of switch circuits 150 respectively corresponding to the current detection modules 121, and each of the switch circuits 150 is electrically connected between the corresponding current detection module 121 and each of the μICs in the corresponding column.

Each of the switch circuits 150 further includes a plurality of switch elements T_{Rx}, T_{Gx}, and T_{Bx}. To simplify matters, FIG. 4 only marks the switch elements T_{R1}-T_{R3}, T_{G1}-T_{G3}, and T_{B1}-T_{B3} of the first column C₁, and the first sub-pixel currents I_{R1}-I_{R3}, the second sub-pixel currents I_{G1}-I_{G3}, and the third sub-pixel currents I_{B1}-I_{B3} respectively flowing therethrough.

Take the first column C₁ for example. The switch elements T_{R1}-T_{R3} of the first column C₁ are respectively electrically connected between a corresponding one of the current detection modules 121 and the first sub-pixel pins R of the μICs in the first column C₁, the switch elements T_{G1}-T_{G3} of the first column C₁ are respectively electrically connected between the corresponding one of the current detection modules 121 and the second sub-pixel pins G of the μICs in the first column C₁, and the switch elements T_{B1}-T_{B3} of the first column C₁ are respectively electrically connected between the corresponding one of the current detection modules 121 and the third sub-pixel pins B of the μICs in the first column C₁.

In the present embodiment, each of the current detection modules 121 includes a sampling resistor 121d and the ADC, and the sampling resistor 121d is electrically connected between the switch circuit 150 and the power circuit 110. With similar function as the current detection module 121 in FIG. 3, the ADC is configured to receive cross-voltages (analog signals) across the sampling resistor 121d to convert the analog signals into digital signals, and to calculate required currents based on the sampling resistor 121d and the cross-voltages.

In the present embodiment, the current detection module 121 may selectively detect the total currents I_{T1}-I_{T3}, the first sub-pixel total current I_{TR1}, the second sub-pixel total current I_{TG1}, the third sub-pixel total current I_{TB1}, the first sub-pixel currents I_{R1}-I_{R3}, the second sub-pixel currents I_{G1}-I_{G3}, or the third sub-pixel currents I_{B1}-I_{B3} through turning on or turning off of each of the switch elements T_{Rx}, T_{Gx}, and T_{Bx} in the switch circuit 150.

Take the first column C₁ for example. If the first sub-pixel total current I_{TR1} needs to be measured, control signals EN_{R1}-EN_{R3} for turning on are provided to respectively turn on the switch elements T_{R1}-T_{R3}. In this manner, the current detection module 121 corresponding to the first column C₁ can detect the first sub-pixel total current I_{TR1} (I_{R1}+I_{R2}+I_{R3}). It should be readily understood that the detection method of the second sub-pixel total current I_{TG1} and the third sub-pixel total current I_{TB1} are the same as or similar to the detection method of the first sub-pixel total current I_{TR1}, so a description in this regard is not provided.

If it is intended to detect the first sub-pixel currents I_{R1}-I_{R3}, the second sub-pixel currents I_{G1}-I_{G3}, or the third sub-pixel currents I_{B1}-I_{B3} on each path individually, a corresponding control signal is provided to turn on the corresponding switch element. For example, if it is intended to detect the first sub-pixel current I_{R1} individually, the control signal E_{NR1} for turning on is provided to turn on the switch element T_{R1}, and the control signal EN_{R2}-EN_{R3}, EN_{G1}-EN_{G3} and EN_{B1}-EN_{B3} for turning off are provided to turn off the remaining switch elements. In this manner, the first sub-pixel current I_{R1} can be individually detected at the current detection module 121 corresponding to the first column C₁. Similarly, the sub-pixel current on each path can be detected individually or together through the above control method.

If the total current I_{T1} of the first column C₁ needs to be detected, the control signals EN_{R1}-EN_{R3}, EN_{G1}-EN_{G3}, and EN_{B1}-EN_{B3} for turning on are provided to turn on all the switch elements T_{R1}-T_{R3}, T_{G1}-T_{G3}, and T_{B1}-T_{B3} in the first column C₁. In this manner, the current detection module 121 corresponding to the first column C₁ can detect the total current I_{T1}.

In summary, based on controlling the turning on or turning off of the switch elements T_{Rx}, T_{Gx}, and T_{Bx}, the current(s) required by each of the columns C₁-Cₙ can be selectively detected at the corresponding current detection module 121. As compared with the embodiment depicted in FIG. 3, the embodiment depicted in FIG. 4 does not require that each of the μICs be configured with the current detection module 121, and the number of the current detection modules 121 can be determined according to the number of columns n of the μICs on the panel 140.

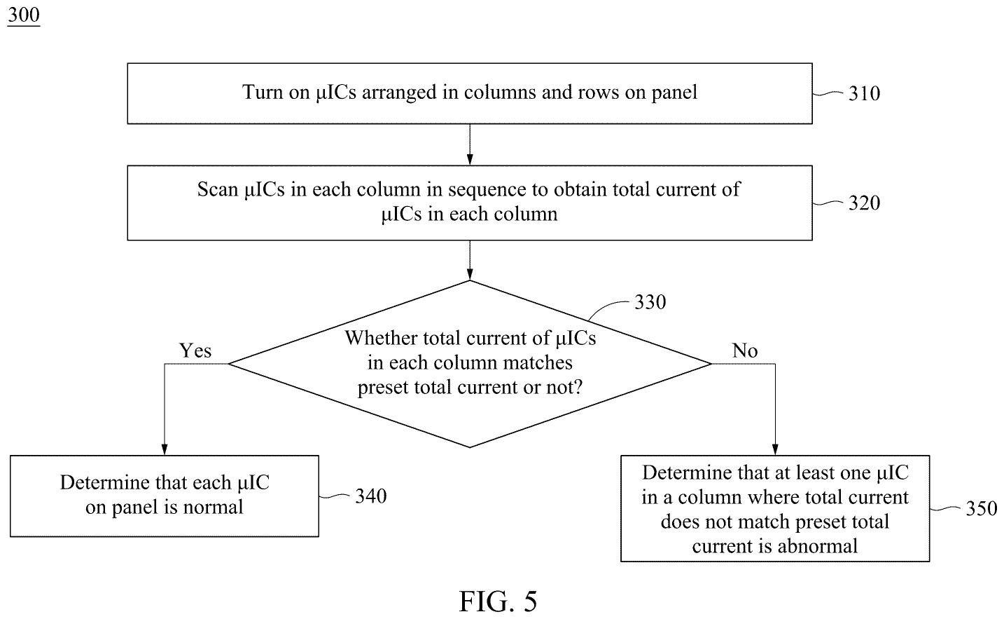

A description is provided with reference to FIG. 5. FIG. 5 depicts a schematic diagram of a μIC detection method 300 according to one embodiment of the present disclosure. The μIC detection method 300 includes Steps 310 to 350, and may be implemented through the configuration shown in FIG. 3, FIG. 4, or another similar configuration.

In Step 310, the μICs arranged in columns and rows on the panel 140 are turned on first. In greater detail, the μICs may be turned on through the power voltage V_{DD} provided by the power circuit 110 of FIG. 1, or may be turned on through an additional power voltage (not shown) provided by the controller 130. It should be understood that regardless of the power voltage V_{DD} provided by the power circuit 110 or the power voltage provided by the controller 130, all or some of the μICs needed to be detected on the panel 140 may be selectively turned on.

In Step 320, the μICs in each of the columns C₁-Cₙ are scanned in sequence to obtain the total currents I_{T1}-I_{T3} of the μICs in each of the columns C₁-Cₙ. In the present embodiment, the scanning signals S₁-Sₙ that are used to scan each of the columns C₁-Cₙ in sequence may be provided by the controller 130, and the controller 130 may be, for example, a timing controller (TCON) in a display device (not shown).

In Step 330, determine whether the total current I_{T1}-I_{T3} of the μICs in each of the columns C₁-Cₙ match a preset total current or not. In greater detail, the current detection circuit 120 detects the total current I_{T1}-I_{T3} of each of the columns C₁-Cₙ, and determines whether the total current I_{T1}-I_{T3} of each of the columns C₁-Cₙ does not match the preset total current or not, for example, exceeds the preset difference value (for instance, plus or minus 5%). When a total current I_{Tx} of the μICs of a column Rₓ does not match the preset total current, for example, exceeds the preset difference value, Step 350 is performed to determine that at least one of the μICs in this column Rₓ is abnormal. Otherwise, Step 340 is performed to determine that each of the μICs on the panel 140 is normal, so that the transfer processes may perform the next-step transfer process of the μLEDs (Step 230) continuously according to the flow 200 shown in FIG. 2.

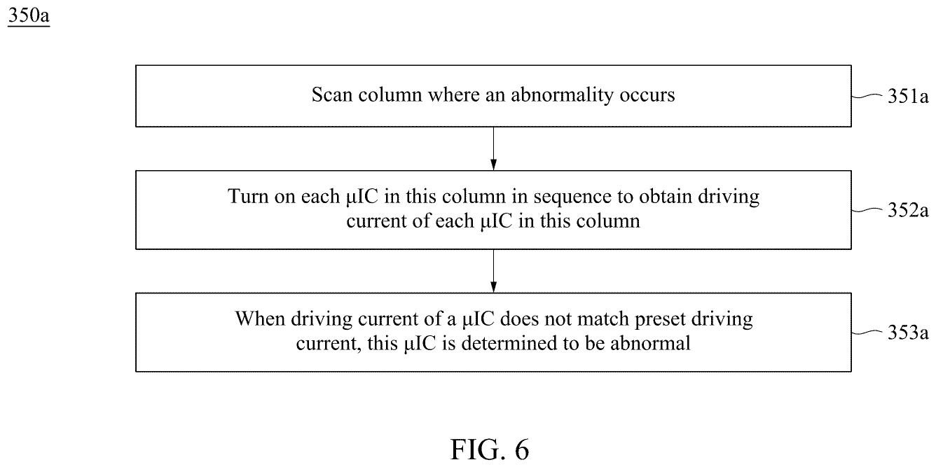

In the embodiment of the present disclosure, Step 350 further includes performing a flow 350a shown in FIG. 6, and which includes Steps 351a to 353a. After performing Step 350, Step 351a of the flow 350a is first performed to scan the column Cₓ where an abnormality occurs according to the scanning signal Sₓ. Then, in Step 352a, each of the μICs in the column Cₓ is turned on in sequence according to the power voltage V_{DD}, so as to obtain a driving current (not shown) of each of the μICs in the column Cₓ. In Step 353a, when the driving current of a μIC in the column Cₓ does not match a preset driving current, for example, exceeds a preset difference value, this μIC is determined to be abnormal.

In greater detail, the driving current of each of the μICs includes the first sub-pixel current I_{Rx}, the second sub-pixel current I_{Gx}, and the third sub-pixel current I_{Bx}, and each of the first sub-pixel current I_{Rx}, the second sub-pixel current I_{Gx}, and the third sub-pixel current I_{Bx} must match the preset driving current or be within the preset difference value before the μICs can be determined to be normal. On the contrary, when one of the first sub-pixel current I_{Rx}, the second sub-pixel current I_{Gx}, and the third sub-pixel current I_{Bx} of a μIC does not match the preset driving current or exceeds the preset difference value, this μIC is determined to be abnormal.

Therefore, based on the μIC detection method 300, not only can whether there is the abnormal μIC(s) in each of the columns C₁-Cₙ be determined through detecting the total current I_{T1}-I_{Tn}, but the abnormal μIC(s) can also be found (for example, which row in the column Cₓ) by detecting the driving current of each of the μICs in the column Cₓ when the abnormal column Cₓ is found.

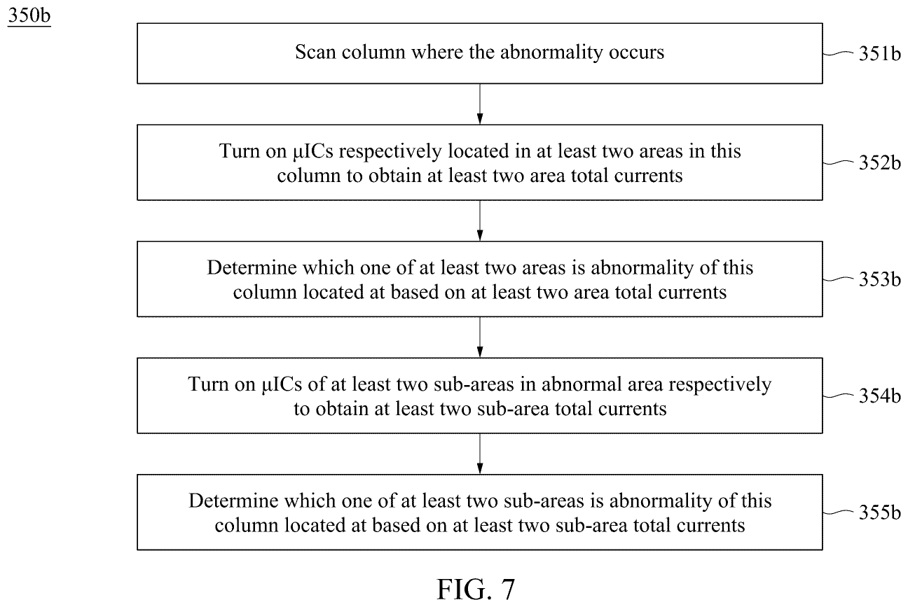

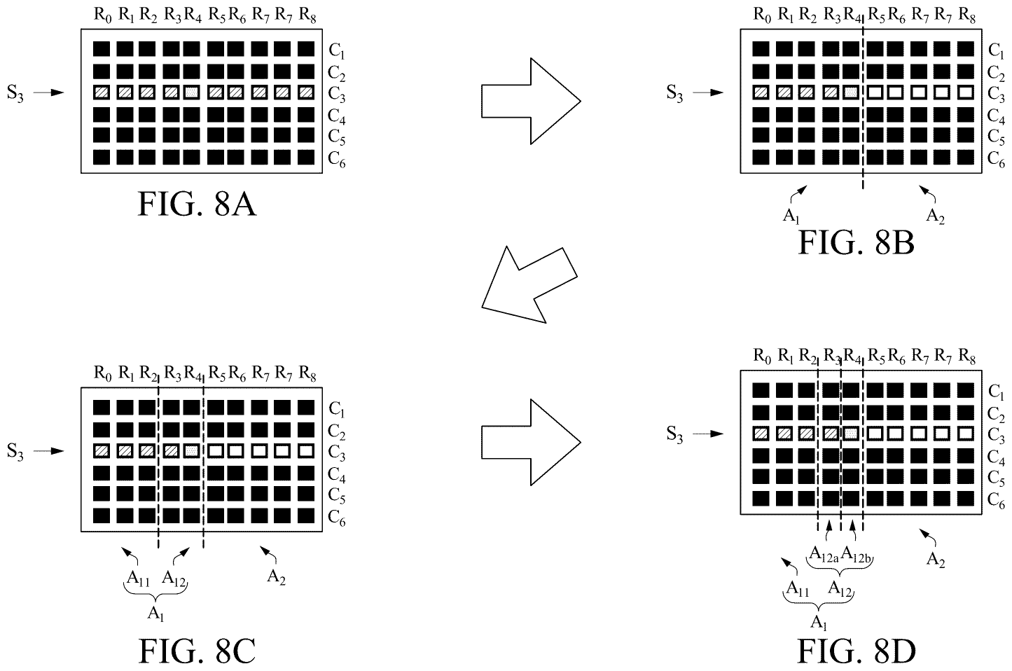

In another embodiment of the present disclosure, Step 350 further includes perform a flow 350b shown in FIG. 7. The flow 350b includes Steps 351b to 353b, and the present disclosure can be better understood with reference to the schematic diagrams depicted in FIGS. 8A to 8D. In FIGS. 8A to 8D, the panel 140 includes a plurality of rows R₀-R₈ and the plurality of columns C₁-C₆, and the panel 140 may be initially divided into an area A₁ and an area A₂. The area A₁ includes the rows R₀-R₄, and the area A₂ includes the rows R₅-R₈. In addition, in order to describe the embodiment conveniently, in the following it is assumed that the μIC of the third row R₃ and the fourth column C₄ is abnormal.

After performing Step 350 to know that the μIC in the third column C₃ has an abnormality, Step 351b is performed continuously to scan the column C₃ where the abnormality occurs according to the scanning signal S₃. Next, in Step 352b, the area A₁ and the area A₂ are turned on in sequence. When the area A₁ is turned on, the power voltage V_{DD} is supplied to the rows R₀-R₄ to turn on each of the μICs in the column C₃ located in the area A₁ corresponding to the scanning signal S₃, so as to obtain an area total current (not shown) of the μICs from the zeroth to the fourth rows R₀-R₄ in the third column C₃ through the current detection circuit 120. When the area A₂ is turned on, the power voltage V_{DD} is supplied to the rows R₅-R₈ to turn on each of the μICs in the column C₃ located in the area A₂ corresponding to the scanning signal S₃, so as to obtain an area total current of the μICs from the fifth to the eighth rows R₅-R₈ in the third column C₃ through the current detection circuit 120. It should be understood that the order of turning on the area A₁ and the area A₂ is not limited in the present disclosure.

In this example, since the abnormal μIC is located in the area A₁ (the third column C₃, the fourth row R₄), the area total current detected from the area A₁ should not match a preset area total current, for example, exceeds a preset difference value. On the contrary, the area total current detected from the area A₂ should match the preset area total current, for example, within the preset difference value. As a result, based on the partitional detection method, the abnormality in the third column C₃ can be further distinguished to be located in the area A₁ faster.

Then, in Step 354b, the μICs of two sub-areas A₁₁, A₁₂ in the abnormal area A₁ are respectively turned on to obtain at least two sub-area total currents (not shown). Additionally, in Step 355b, which one of the two sub-areas A₁₁, A₁₂ is the abnormality of the column C₃ located at is determined based on the sub-area total currents of the two sub-areas A₁₁, A₁₂.

In greater detail, Step 354b and Step 355b are similar to Step 352b and Step 353b. In Step 354b, the sub-area A₁₁ and the sub-area A₁₂ in the area A₁ are turned on in sequence. When the sub-area A₁₁ is turned on, the power voltage V_{DD} is supplied to the rows R₀-R₂ to turn on the μICs in the column C₃ located in the sub-area A₁₁ corresponding to the scanning signal S₃, so as to obtain the sub-area total current of the μICs from the zeroth to the second rows R₀-R₂ in the third column C₃ through the current detection circuit 120. After that, the sub-area A₁₂ is turned on to supply the power voltage V_{DD} to the rows R₃-R₄ to turn on the μICs in the column C₃ located in the area A₁₂ corresponding to the scanning signal S₃, so as to obtain the sub-area total current of the μICs from the third to the fourth rows R₃-R₄ in the third column C₃ through the current detection circuit 120. It should be understood that the order of turning on the sub-area A₁₁ and the sub-area A₁₂ is not limited in the present disclosure.

Since the abnormal μIC is located in the sub-area A₁₂ (the third column C₃, the fourth row R₄), the sub-area total current detected from the area A₁₂ should not match a preset sub-area total current, for example, a difference value between the sub-area total current detected from the sub-area A₁₂ and the preset sub-area total current exceeds a preset difference value. On the contrary, the sub-area total current detected from the area A₁₁ should match the preset sub-area total current, for example, a difference value between the sub-area total current detected from the sub-area A₁₁ and the preset sub-area total current is within the preset difference value. In this manner, based on the partitional detection method, the abnormality in the third column C₃ can be further distinguished to be located in the sub-area A₁₂.

FIG. 8D divides the abnormal sub-area A₁₂ again into sub-areas A₁₂ₐ and A_{12b} according to the partitional detection method in the previous steps, and detects whether each of sub-area total currents matches a preset sub-area total current or not. It should be understood that the number of dividing for the area detection depends on a size of the panel 140 and a number of rows Rₙ of the μICs on the panel 140. When the panel 140 has more (or fewer) rows, the times for performing area detection will increase (or decrease) accordingly until which area, which row, and which column the abnormal IC is located at is found. As compared with the flow 350a shown in FIG. 6 in which the rows R₀-R₈ are detected in sequence, the flow 350b shown in FIG. 7 may effectively shorten the detection and debugging time through the partitional detection method.

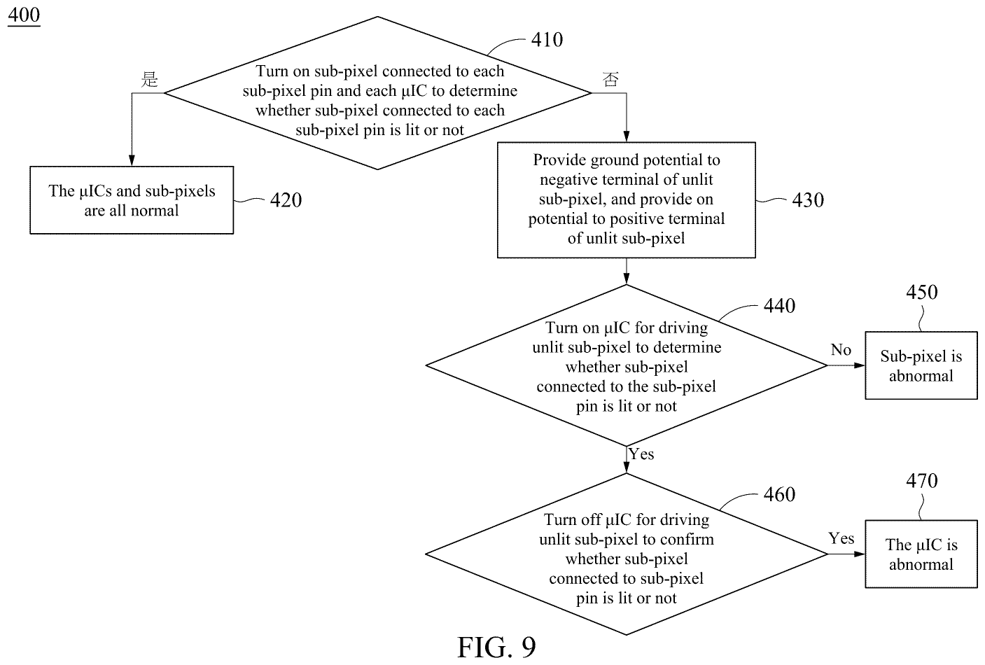

A description is provided with reference to FIG. 9. In some embodiments, when both the μICs and the μLEDs (that is, the sub-pixels) have been transferred to the panel 140 before the detection, the μIC detection method 300 further includes performing a flow 400. The flow 400 includes Steps 410 to 470.

In greater detail, each of the μICs includes a plurality of sub-pixel pins (that is, the first sub-pixel pin R, the second sub-pixel pin G, and the third sub-pixel pin B), and each of the sub-pixel pins includes a positive terminal and a negative terminal to be configured to be respectively connected to a first sub-pixel, a second sub-pixel, and a third sub-pixel. During the detection, the sub-pixels connected to each of the sub-pixel pins and each of the μICs are turned on at Step 410 first to determine whether the sub-pixel of each of the sub-pixel pin is lit or not. When all the sub-pixels connected to the sub-pixel pins are lit, it is determined that the μICs and the sub-pixels on the panel 140 are all normal (Step 420).

On the contrary, when the sub-pixel connected to the sub-pixel pin is not lit, it is determined that one of the μIC and the sub-pixel is abnormal, and Step 430 is performed to provide a ground potential through the power circuit 110 to a negative terminal of the unlit sub-pixel, and provide an on potential (such as 5V) through the controller 130 to a positive terminal of the unlit sub-pixel. In such an embodiment, the current detection circuit 120 is not activated, and may be turned off or bypassed.

Then, in Step 440, the μIC for driving the unlit sub-pixel is turned on again to determine whether the sub-pixel connected to the sub-pixel pins is lit or not. When the sub-pixel connected to the sub-pixel pin is still not lit, it means that the μIC is actually under control, so it is determined that the μIC is normal and the sub-pixel is abnormal (Step 450). On the contrary, Step 460 is performed continuously to turn off the μIC for driving the unlit sub-pixel, and confirm whether the sub-pixel connected to the sub-pixel pin is lit or not. When the sub-pixel connected to the sub-pixel pin is lit, it means that the μIC is actually not controlled, and it is determined that the μIC is abnormal and the sub-pixel is normal (Step 470).

According to the μIC detection system and detection method thereof of the present disclosure, through the current detection method, multiple μICs distributed on the panel are detected, and the difference value between the detected total current and the preset total current is compared to determine whether the μICs in each of the columns have the abnormity or not. In addition to that, the detailed location of the abnormal μIC on the panel is further determined based on the preset driving current of the μICs. In summary, the present disclosure can effectively detect whether each of the μICs in each of the columns has the abnormality or not to further perform repair or replacement in advance, thus improving the overall efficiency of the mass transfer process.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the present disclosure. In view of the foregoing, it is intended that the present disclosure covers modifications and variations of this disclosure provided they fall within the scope of the following claims and their equivalents.

What is claimed is:

1. A micro-integrated circuit (μIC) detection method applicable for detecting a plurality of μICs on a panel, the detection method comprising:
turning on the μICs arranged in columns and rows on the panel;
scanning the μICs in each of the columns in sequence to obtain a total current of the μICs in each of the columns; and
determining that at least one of the μICs in one of the columns is abnormal in response to the total current of the μICs in the one of the columns not matching a preset total current.

2. The detection method of claim 1, wherein in response to determining that the at least one of the μICs in the one of the columns is abnormal, the detection method further comprises:
scanning the one of the columns where the total current of the μICs in the one of the columns does not match the preset total current;
turning on each of the μICs in the one of the columns in sequence to obtain a driving current of each of the μICs in the one of the columns; and
determining that one of the μICs in the one of the columns is abnormal in response to the driving current of each of the μICs in the one of the columns not matching a preset driving current.

3. The detection method of claim 1, wherein the panel comprises at least two areas, and in response to determining that the at least one of the μICs in one of the columns is abnormal, the detection method further comprises:
scanning the one of the columns where the total current of the μICs in the one of the columns does not match the preset total current;
turning on the μICs respectively located in the at least two areas in the one of the columns in sequence to obtain at least two area total currents;
determining that an abnormality has occurred in one of the at least two areas in response to the at least two area total currents of the at least two areas not matching a preset area total current;
turning on the μICs respectively located in at least two sub-areas of the one of the at least two areas to obtain at least two sub-area total currents; and
determining that the abnormality has occurred in one of the at least two sub-areas in response to the at least two sub-area total currents of the at least two sub-areas not matching a preset sub-area total current.

4. The detection method of claim 1, wherein each of the μICs comprises a plurality of sub-pixel pins, each of the sub-pixel pins comprises a positive terminal and a negative terminal, and the positive terminal and the negative terminal are configured to be connected to a sub-pixel, the detection method further comprises:
turning on the sub-pixel connected to each of the sub-pixel pins and each of the μICs to determine whether the sub-pixel connected to each of the sub-pixel pins is lit or not;
providing a ground potential to a negative terminal of an unlit sub-pixel connected to one of the sub-pixel pins, and providing an on potential to a positive terminal of the unlit sub-pixel connected to the one of the sub-pixel pins;
turning on a corresponding one of the μICs for driving the unlit sub-pixel, wherein when the unlit sub-pixel is still not lit, determining that the unlit sub-pixel is abnormal; and
turning off the corresponding one of the μICs for driving the unlit sub-pixel, wherein when the unlit sub-pixel is lit, determining that the corresponding one of the μICs is abnormal.

5. A micro-integrated circuit (μIC) detection system applicable for detecting a plurality of μICs arranged in columns and rows on a panel, the detection system comprising:
a controller electrically connected to the μICs and configured to provide a scanning signal so as to scan the μICs in each of the columns in sequence;
a power circuit configured to provide a power voltage to turn on the μICs; and
a current detection circuit electrically connected between the power circuit and the μICs and configured to detect a total current of the μICs in each of the columns after being scanned by the scanning signal, wherein at least one of the μICs in one of the columns is determined to be abnormal in response to the total current of the μICs in the one of the columns not matching a preset total current.

6. The detection system of claim 5, wherein each of the μICs further comprises a first sub-pixel pin, a second sub-pixel pin, and a third sub-pixel pin, and the current detection circuit further comprises:
a plurality of current detection modules respectively corresponding to the μICs, and configured to detect a first sub-pixel current, a second sub-pixel current, and a third sub-pixel current respectively flowing through the first sub-pixel pin, the second sub-pixel pin, and the third sub-pixel pin of each of the μICs.

7. The detection system of claim 6, wherein each of the current detection modules further comprises:
a first testing pad corresponding to the first sub-pixel pin;
a second testing pad corresponding to the second sub-pixel pin; and
a third testing pad corresponding to the third sub-pixel pin.

8. The detection system of claim 6, wherein each of the current detection modules further comprises:
a first sampling resistor electrically connected between the first sub-pixel pin and the power circuit;
a second sampling resistor electrically connected between the second sub-pixel pin and the power circuit; and
a third sampling resistor electrically connected between the third sub-pixel pin and the power circuit.

9. The detection system of claim 8, wherein each of the current detection modules further comprises:
an analog-to-digital converter (ADC) configured to receive cross-voltages across the first sampling resistor, the second sampling resistor, and the third sampling resistor to obtain the first sub-pixel current, the second sub-pixel current, and the third sub-pixel current.

10. The detection system of claim 5, wherein the total current comprises a first sub-pixel total current, a second sub-pixel total current, and a third sub-pixel total current, and each of the μICs further comprises:
a first sub-pixel pin configured to allow a first sub-pixel current to flow through during a detection period;
a second sub-pixel pin configured to allow a second sub-pixel current to flow through during the detection period; and
a third sub-pixel pin configured to allow a third sub-pixel current to flow through during the detection period;
wherein the first sub-pixel total current is a sum of the first sub-pixel current of each of the μICs in a same one of the columns, the second sub-pixel total current is a sum of the second sub-pixel current of each of the μICs in the same one of the columns, the third sub-pixel total current is a sum of the third sub-pixel current of each of the μICs in the same one of the columns.

11. The detection system of claim 10, wherein the current detection circuit further comprises a plurality of current detection modules respectively corresponding to the columns and configured to detect the total current of each of the columns, and the detection system further comprises:
a plurality of switch circuits respectively corresponding to the current detection modules, and each of the switch circuits being electrically connected between a corresponding one of the current detection modules and each of the μICs in the same one of the columns.

12. The detection system of claim 11, wherein each of the switch circuits further comprises:
a plurality of first switch elements respectively electrically connected between the corresponding one of the current detection modules and the first sub-pixel pin of each of the μICs in the same one of the columns.

13. The detection system of claim 12, wherein each of the switch circuits further comprises:
a plurality of second switch elements respectively electrically connected between the corresponding one of the current detection modules the second sub-pixel pin of each of the μICs in the same one of the columns.

14. The detection system of claim 13, wherein each of the switch circuits further comprises:
a plurality of third switch elements respectively electrically connected between the corresponding one of the current detection modules and the third sub-pixel pin of each of the μICs in the same one of the columns.

15. The detection system of claim 11, wherein each of the plurality of current detection modules further comprises:
a sampling resistor electrically connected between the power circuit and the corresponding one of the plurality of switch circuits; and
an ADC configured to receive cross-voltage across the sampling resistor to selectively obtain the first sub-pixel current, the second sub-pixel current, the third sub-pixel current, the first sub-pixel total current, the second sub-pixel total current, the third sub-pixel total current or the total current depending on whether the plurality of switch circuits are turned on or turned off.

16. The detection system of claim 15, wherein each of the plurality of current detection modules further comprises:
a testing pad electrically connected between the sampling resistor and the corresponding one of the plurality of switch circuits.
